(19) United States
(12) Patent Application Publication
(10) Pub. No.: US 2024/0113087 A1
(43) Pub. Date: Apr. 4, 2024

(54) HIGH PERFORMANCE PERMANENT GLASS ARCHITECTURES FOR STACKED INTEGRATED CIRCUIT DEVICES

(71) Applicant: Intel Corporation, Santa Clara, CA (US)

(72) Inventors: Brandon Marin, Gilbert, AZ (US); Gang Duan, Chandler, AZ (US); Srinivas Pietambaram, Chandler, AZ (US); Suddhasattwa Nad, Chandler, AZ (US); Jeremy Ecton, Gilbert, AZ (US); Debendra Mallik, Chandler, AZ (US); Ravindranath Mahajan, Chandler, AZ (US); Rahul Manepalli, Chandler, AZ (US)

(73) Assignee: Intel Corporation, Santa Clara, CA (US)

(21) Appl. No.: 17/957,403

(22) Filed: Sep. 30, 2022

(51) Int. Cl. H01L 25/10; H01L 21/48; H01L 23/00; H01L 23/13; H01L 23/16; H01L 23/473; H01L 23/538; H01L 25/00; H01L 25/18

(52) U.S. Cl. CPC H01L 25/105; H01L 21/486; H01L 23/13; H01L 23/16; H01L 23/473; H01L 23/5384; H01L 23/5386; H01L 24/24; H01L 25/18; H01L 25/50; H01L 24/16; H01L 24/73; H01L 24/92; H01L 2224/16235; H01L 2224/24101; H01L 2224/24227; H01L 2224/73259; H01L 2224/92224; H01L 2225/1023; H01L 2225/1035; H01L 2225/1094

(57) ABSTRACT

An apparatus is provided which comprises: an interposer comprising glass, one or more redistribution layers on a first interposer surface, one or more conductive contacts on a second interposer surface opposite the first interposer surface, one or more vias through the interposer coupling at least one of the conductive contacts on the second interposer surface with the redistribution layers on the first interposer surface, an integrated circuit device embedded within a cavity in the interposer between the first and second interposer surfaces, the embedded integrated circuit device coupled with a first redistribution layers surface, a stack of two or more integrated circuit devices coupled with a second redistribution layers surface opposite the first redistribution layers surface, and mold material surrounding at least one side of the stack of two or more integrated circuit devices. Other embodiments are also disclosed and claimed.

### BACKGROUND

Computing platforms, such as desktops, laptops or smart phones, for example, are expected to have increased performance compared with previous iterations. One way that manufacturers of computing platforms can achieve increased performance is by integrating more integrated circuit devices into a single package. Heterogeneous integration refers to the integration of separately manufactured components into an assembly that, in the aggregate, provides enhanced functionality and improved operating characteristics. As more computing cores are integrated into a package, or system on a chip, there arises a need to integrate more memory components into the package as well. With increased integration, there can arise issues with warpage, power delivery, and thermal management within device packages. Therefore, there is a need for high performance architectures that address these issues.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of an example high performance glass architecture for stacked integrated circuit devices, according to some embodiments,

FIGS. 2A-2F illustrate cross-sectional views of manufacturing steps of forming a high performance glass architecture for stacked integrated circuit devices, according to some embodiments,

FIG. 3 illustrates a cross-sectional view of an example high performance glass architecture for stacked integrated circuit devices, according to some embodiments,

FIG. 4 illustrates a cross-sectional view of an example high performance glass architecture for stacked integrated circuit devices, according to some embodiments,

FIG. 5 illustrates a flowchart of a method of forming a high performance glass architecture for stacked integrated circuit devices, in accordance with some embodiments, and

FIG. 6 illustrates a smart device or a computer system or a SoC (System-on-Chip) which includes a high performance glass architecture for stacked integrated circuit devices, according to some embodiments.

### DETAILED DESCRIPTION

High performance glass architectures for stacked integrated circuit devices are generally presented. In this regard, embodiments of the present disclosure enable glass interposers for embedded and stacked devices. One skilled in the art would appreciate that these glass interposers may enable more devices, such as memory devices, to be integrated in a stacked die package. Additionally, the architectures described herein may offer improved thermal management, power delivery, and reliability, and thereby enable enhanced features.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

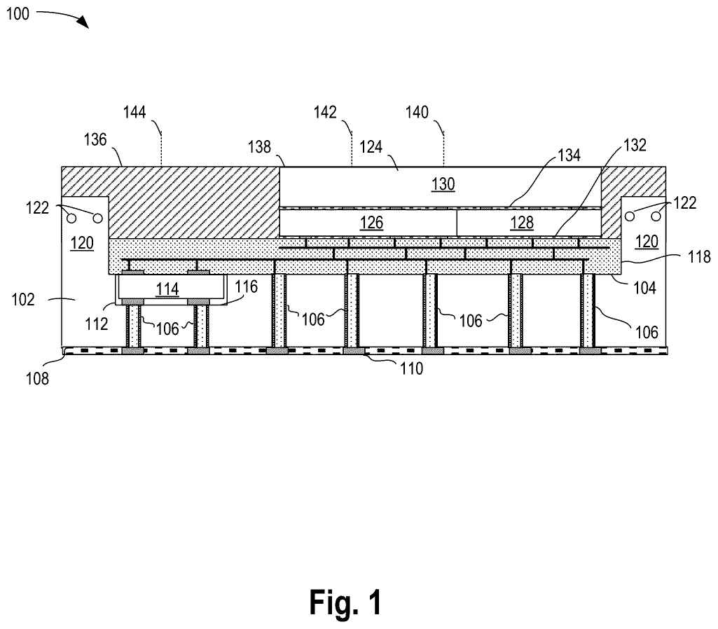

FIG. 1 illustrates a cross-sectional view of an example high performance glass architecture for stacked integrated circuit devices, according to some embodiments. As shown, device package 100 includes glass interposer 102, upper interposer surface 104, vias 106, lower interposer surface 108, conductive contacts 110, interposer cavity 112, embedded device 114, cavity surface 116, redistribution layers 118, interposer extensions 120, channels 122, integrated circuit device stack 124, integrated circuit device 126, integrated circuit device 128, integrated circuit device 130, device interconnect 132, device interconnect 134, mold material 136, device stack surface 138, device stack midpoint 140, interposer midpoint 142, and embedded device midpoint 144. In some embodiments, device package 100 may include additional layers and integrate additional components.

In some embodiments, glass interposer 102 may be a silicate (for example silicon dioxide-based) glass that may be tempered or treated. In some embodiments, glass interposer 102 is a non-crystalline amorphous solid. In some embodiments, glass interposer 102 may be designed to be thin and damage-resistant. In some embodiments, glass interposer 102 is preformed and not deposited in-situ using a traditional deposition technique, such as atomic layer deposition or chemical vapor deposition, for example. In some embodiments, glass interposer 102 is made by fusing liquid sand with soda ash (sodium carbonate), limestone (calcium carbonate), and/or other ingredients and cooling rapidly. In some embodiments, glass interposer 102 may contain boron oxide for improved thermal resistance. In some embodiments, glass interposer 102 may contain lead oxide for improved ease of cutting. In some embodiments, glass interposer 102 may contain a sandwich or laminate of multiple layers of glass that are plastic bonded together. In some embodiments, glass interposer 102 is transparent or translucent. In some embodiments, glass interposer 102 may have a thickness of between about 1 and 10 millimeters. Glass interposer 102 may have an inherently low surface roughness and a high temperature tolerance, allowing for uniform thin film depositions that require annealing. In some embodiments, glass interposer 102 may have a relatively low coefficient of thermal expansion (CTE). In some embodiments, glass interposer 102 may also contain ceramic material. In some embodiments, the thermal expansion of glass interposer 102 is controlled by firing to create crystalline species that will influence the overall expansion of glass interposer 102 in the desired direction. For example, glass interposer 102 may include crystalline additives that tend to thermally expand longitudinally, as opposed to laterally. In some embodiments, the formulation of glass interposer 102 employs materials delivering particles of the desired expansion to the matrix. In some embodiments, glass interposer 102 may include a glaze (not shown) that may have the effect of reducing thermal expansion.

Vias 106 may be drilled through glass interposer 102 by any known method, including, for example, laser drilling and plating, to provide electrical pathways from upper interposer surface 104 to lower interposer surface 108. Vias 106 may also be lined and/or filled with additional dielectric material to provide electrical insulation. While vias 106 are also shown as being present between cavity surface 116 and lower interposer surface 108, vias 106 are not included there in some embodiments.

Interposer cavity 112, may be formed below upper interposer surface 104 by any known method, including, but not limited to, chemical or mechanical etching. While shown as extending down to cavity surface 116, in some embodiments, interposer cavity 112 may extend from upper interposer surface 104 completely through to lower interposer surface 108. Also, while shown as including a single interposer cavity 112, any number of interposer cavities may be incorporated with similar or varying depths.

In some embodiments, embedded device 114 represents an integrated circuit device. In some embodiments, embedded device 114 may be a memory device, such as a high bandwidth memory (HBM). In some embodiments, embedded device 114 may be an intelligent power device (IPD). In other embodiments, embedded device 114 may be a photonic integrated circuit (PIC) or an embedded passive component (EPC). While shown as being a single device, embedded device 114 may be implemented as a stack of multiple homogeneous or heterogeneous devices.

Redistribution layers 118 may be formed over embedded device 114 and upper interposer surface 104. In some embodiments, redistribution layers 118 may include multiple layers of interlayer dielectric, such as a doped silicon dioxide, for example, along with metal wires to route contacts of vias 106 and embedded device 114 to device interconnect 132. In some embodiments, redistribution layers 108 may fan-in a contact pitch from upper interposer surface 104 to device interconnect 132.

Interposer extensions 120 may be present to provide enhanced mechanical support and/or thermal management for integrated circuit device stack 124. In some embodiments interposer extensions 120 may be formed as part of glass interposer 102, while in other embodiments, interposer extensions 120 may be formed separately of similar or different material from glass interposer 102. In some embodiments, interposer extensions 120 may include channels 122. In some embodiments, channels 122 may be pathways through interposer extensions 120 through which fluid may be able to flow when incorporated with an active thermal solution, for example including tubing and pumps (not shown).

Integrated circuit device stack 124 represents a stack of integrated circuit devices that may include more or fewer devices than shown. As shown, integrated circuit device stack 124 includes integrated circuit devices 126 and 128, which are bonded with redistribution layers 118 through device interconnect 132. In some embodiments, device interconnect 132 may represent traditional solder bonding. In other embodiments, device interconnect 132 may represent hybrid bonding. Integrated circuit device 130 may be bonded with integrated circuit devices 126 and 128 through device interconnect 134. In some embodiments, device interconnect 134 may represent a direct chip to chip interconnect using high bandwidth interconnect (HBI). In some embodiments, integrated circuit devices 126, 128, and/or 130 may represent controllers, processors, or system-on-a-chip (SOCs), such as multi-core processors, for example.

Mold material 136 may surround one or more sides of integrated circuit device stack 124. In some embodiments, mold material 136 is a highly thermally conductive epoxy mold, for example with filler material, such as alumina, crystalline silica, or aluminum nitride, for example. In some embodiments, mold material 136 is formed to be coplanar with device stack surface 138.

In some embodiments, device stack midpoint 140 may be offset to one side of interposer midpoint 142 while embedded device midpoint 144 is offset to the opposite side of interposer midpoint 142.

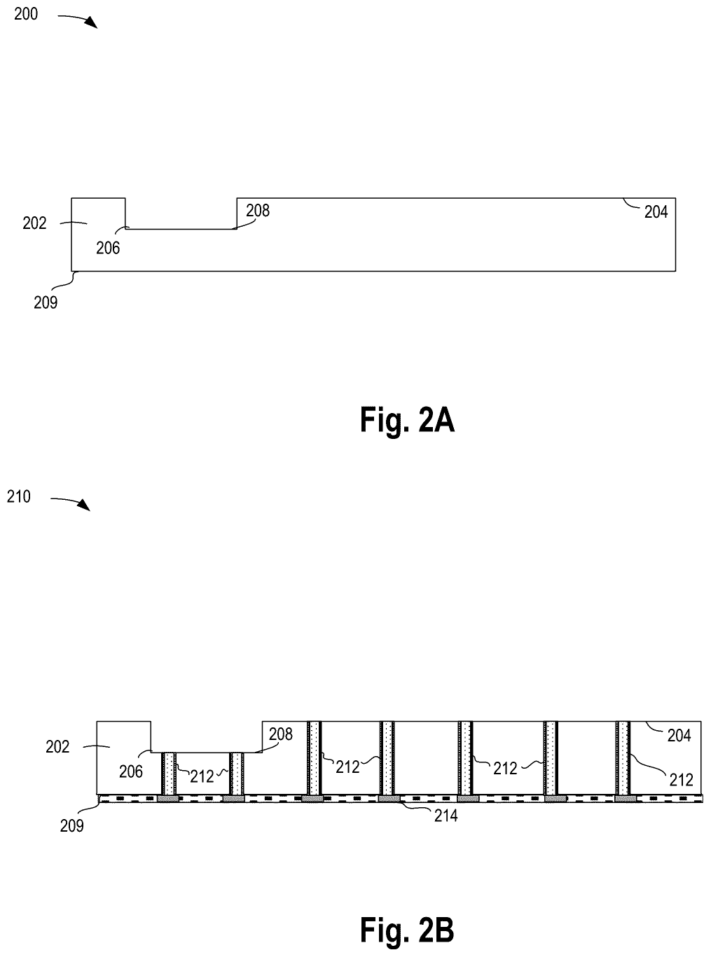

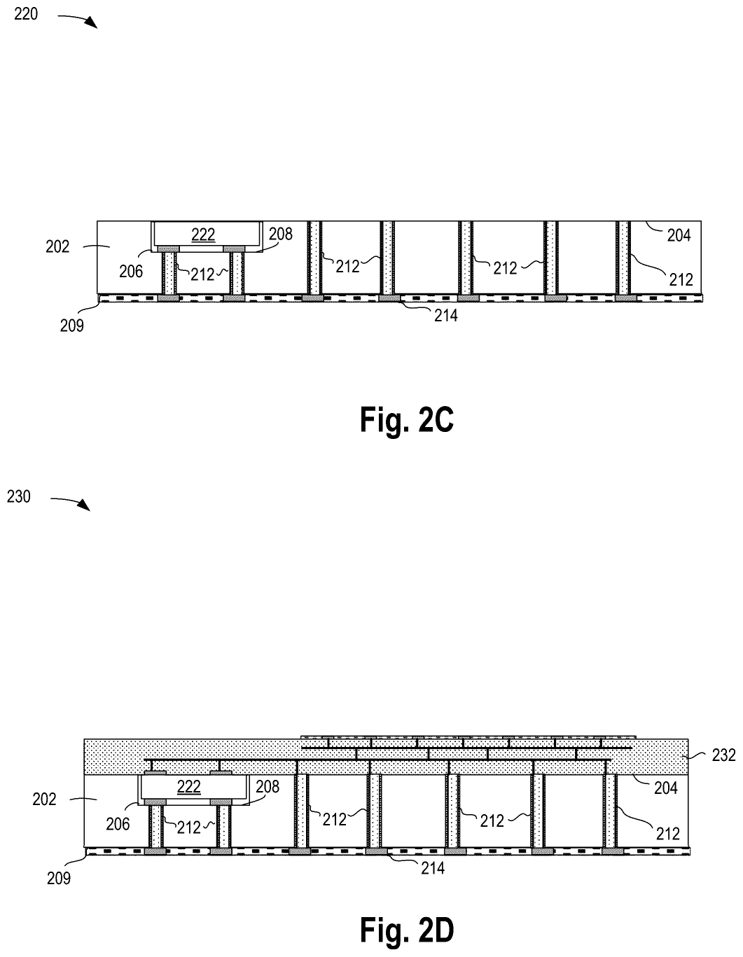

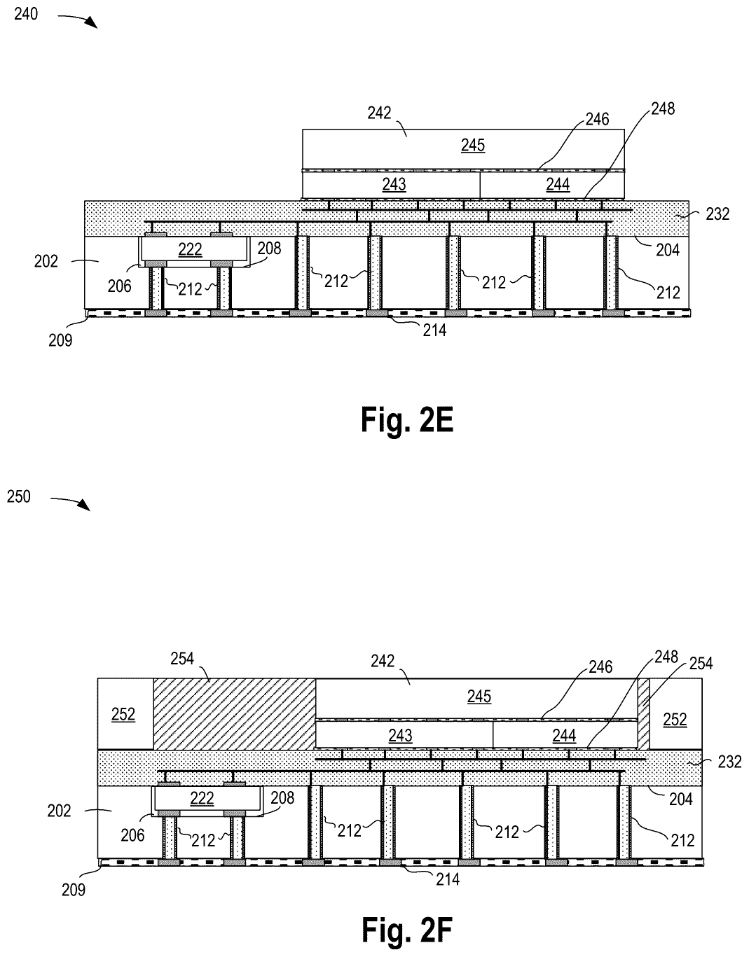

FIGS. 2A-2F illustrate cross-sectional views of manufacturing steps of forming high performance glass architecture for stacked integrated circuit devices, according to some embodiments. As shown in FIG. 2A, assembly 200 includes glass interposer 202, upper interposer surface 204, interposer cavity 206, cavity surface 208, and lower interposer surface 209. In some embodiments, glass interposer 202 may be a preformed piece of glass including interposer cavity 206 and any of the properties mentioned previously, for example in reference to FIG. 1. In some embodiments, interposer cavity 206 is formed separately by removing a portion of glass interposer 202 below upper interposer surface 209 to cavity surface 208. While shown as including square sidewalls, interposer cavity 206 may include angled sidewalls. In some embodiments, interposer cavity 206 may extend from upper interposer surface 204 to lower interposer surface 209. While shown as including one interposer cavity 206, any number of interposer cavities 206 may be present. In some embodiments, the distance from upper interposer surface 204 to cavity surface 208 is selected based on the height of one or more devices to be embedded within interposer cavity 206.

FIG. 2B shows assembly 210, which may include vias 212 and conductive contacts 214. In some embodiments, vias 212 may include conductive material, such as metal, with additional insulative material surrounding (and/or surrounded by) the conductive material. Vias 212 may be formed by laser drilling or any other known method. Conductive contacts 214 may include discrete conductive contacts, such as copper, for each via 212 to enable coupling with another component, such as a package substrate or system board, for example. While shown as including vias 212 between cavity surface 208 and lower interposer surface 209, in some embodiments, vias 212 are not present below interposer cavity 206.

As shown in FIG. 2C, assembly 220 includes device 222. In some embodiments, device 222 may be coupled with vias 212 at cavity surface 208 through solder bonding. Device 222 may represent any type of semiconductor device, including, but not limited to, high bandwidth memory (HBM), intelligent power device (IPD), photonic integrated circuit (PIC), and embedded passive components (EPC). While shown as being a single device 222, in some embodiments a stack of multiple devices may be placed in interposer cavity 206.

Turning now to FIG. 2D, assembly 230 may include redistribution layers 232 over upper interposer surface 204 and device 222, thereby embedding device 222 within interposer cavity 206. In some embodiments, redistribution layers 232 may include multiple layers of metal routing, such as copper, and interlayer dielectric to insulate and cover the metal. In some embodiments, redistribution layers 232 may include a dielectric material deposited by any known technique, including, but not limited to, atomic layer deposition or chemical vapor deposition. In some embodiments, redistribution layers 232 may fan-in a wider contact pitch below, at upper interposer surface 204, to a narrower contact pitch above redistribution layers 232.

FIG. 2E shows assembly 240, which may include device stack 242, integrated circuit device 243, integrated circuit device 244, integrated circuit device 245, interconnect 246, and interconnect 248. As shown, integrated circuit device stack 124 includes integrated circuit devices 243 and 244, which are bonded with redistribution layers 232 through interconnect 248. In some embodiments, interconnect 248 may represent traditional solder bonding. In other embodiments, interconnect 248 may represent hybrid bonding. Integrated circuit device 245 may be bonded with integrated circuit devices 243 and 244 through interconnect 246. In some embodiments, interconnect 246 may represent a direct chip to chip interconnect using high bandwidth interconnect (HBI). In some embodiments, integrated circuit devices 243, 244, and/or 245 may represent controllers or processors, such as multi-core processors, for example

As shown in FIG. 2F, for assembly 250 frame 252 and mold material 254 may have been deposited. In some embodiments, frame 252 is adjacent at least one side of device stack 242 to provide mechanical and/or thermal management support. In some embodiments, frame 252 surrounds all four lateral sides of device stack 242. While shown as having a comparable height to device stack 242, in some embodiments, frame 252 has a different height than device stack 242. In some embodiments, frame 252 includes channels for fluid circulation as described previously, for example in relation to FIG. 1. Frame 252 may include joined segments forming a square or may be disjointed. In some embodiments, frame 252 comprises glass. In some embodiments, frame 252 comprises copper.

Mold material 254 may fill in any spaces between frame 252 and device stack 242. In some embodiments, mold material 254 is an epoxy resin with filler material, such as metallic or ceramic material, for example, to provide enhanced thermal conductivity. In some embodiments, any excess mold material 254 above a top surface of device stack 242 may be removed.

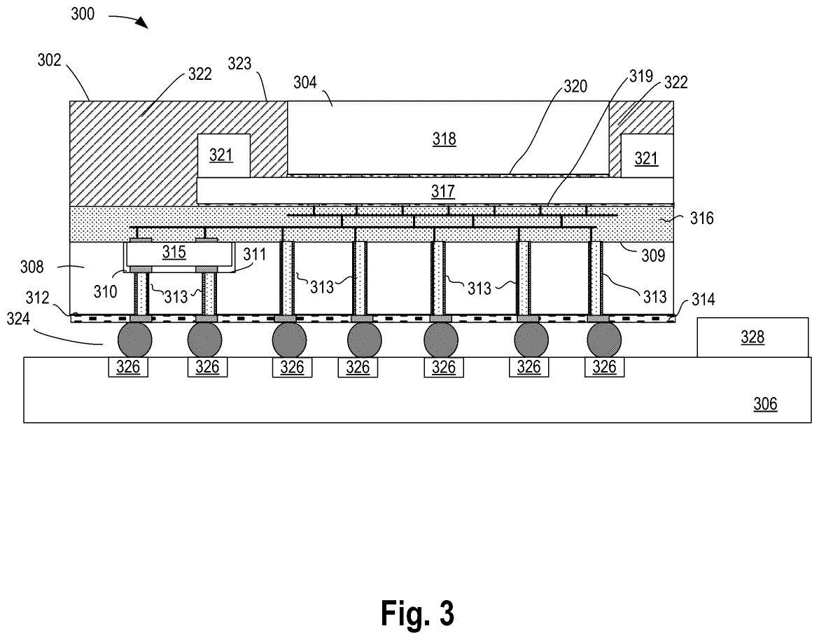

FIG. 3 illustrates a cross-sectional view of an example high performance glass architecture for stacked integrated circuit devices, according to some embodiments. As shown, assembly 300 includes device package 302, integrated circuit device stack 304, system board 306, glass interposer 308, glass interposer top surface 309, glass interposer cavity 310, cavity surface 311, glass interposer bottom surface 312, vias 313, bottom surface contacts 314, embedded integrated circuit device 315, redistribution layers 316, bottom integrated circuit device 317, top integrated circuit device 318, device interconnect 319, device interconnect 320, die stack frame 321, mold material 322, device package surface 323, solder balls 324, board pads 326, and board component 328.

Device package 302 may incorporate elements previously discussed in reference to prior figures. For example, die stack frame 321 may have properties discussed in reference to FIG. 1 or 2A-2F. As shown, device package 302 may include integrated circuit device stack 304 with narrower top integrated circuit device 318 stacked on wider bottom integrated circuit device 317. In this example embodiment, die stack frame 321 is placed on top of bottom integrated circuit device 317 and surrounds top integrated circuit device 317.

In some embodiments, solder balls 324 may be formed on bottom surface contacts 314, thereby allowing device package 302 to be soldered to system board 306 through board pads 326. System board 306 may also incorporate board component 328, which may represent any type of active or passive system components, such as a power supply, memory devices, voltage regulators, I/O interfaces, etc.

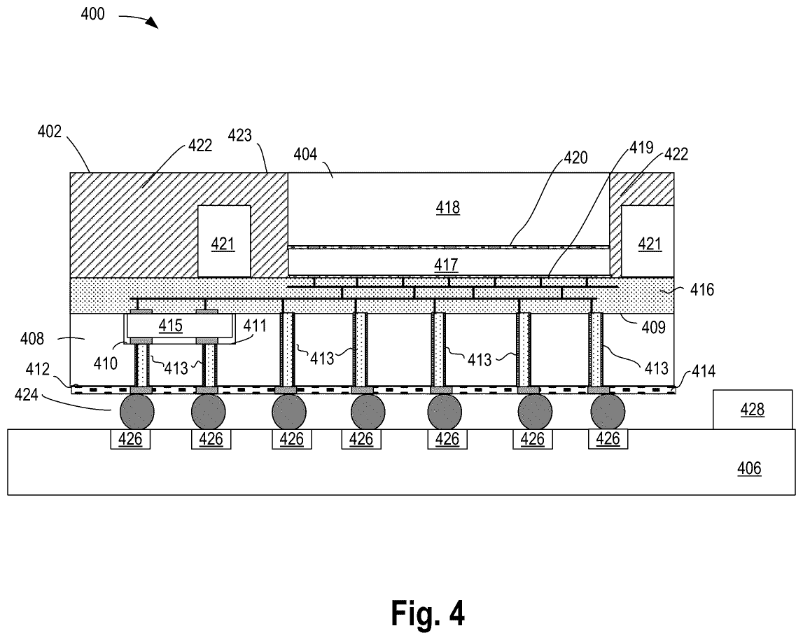

FIG. 4 illustrates a cross-sectional view of an example high performance glass architecture for stacked integrated circuit devices, according to some embodiments. As shown, assembly 400 includes device package 402, integrated circuit device stack 404, system board 406, glass interposer 408, glass interposer top surface 409, glass interposer cavity 410, cavity surface 411, glass interposer bottom surface 412, vias 413, bottom surface contacts 414, embedded integrated circuit device 415, redistribution layers 416, bottom integrated circuit device 417, top integrated circuit device 418, device interconnect 419, device interconnect 420, die stack frame 421, mold material 422, device package surface 423, solder balls 424, board pads 426, and board component 428.

Device package 402 may incorporate elements previously discussed in reference to prior figures. For example, die stack frame 421 may have properties discussed in reference to FIG. 1 or 2A-2F. As shown, device package 402 may include integrated circuit device stack 404 with taller top integrated circuit device 418 stacked on shorter bottom integrated circuit device 417. In this example embodiment, die stack frame 421 is placed on top of redistribution layers 416 and surrounds integrated circuit device stack 404.

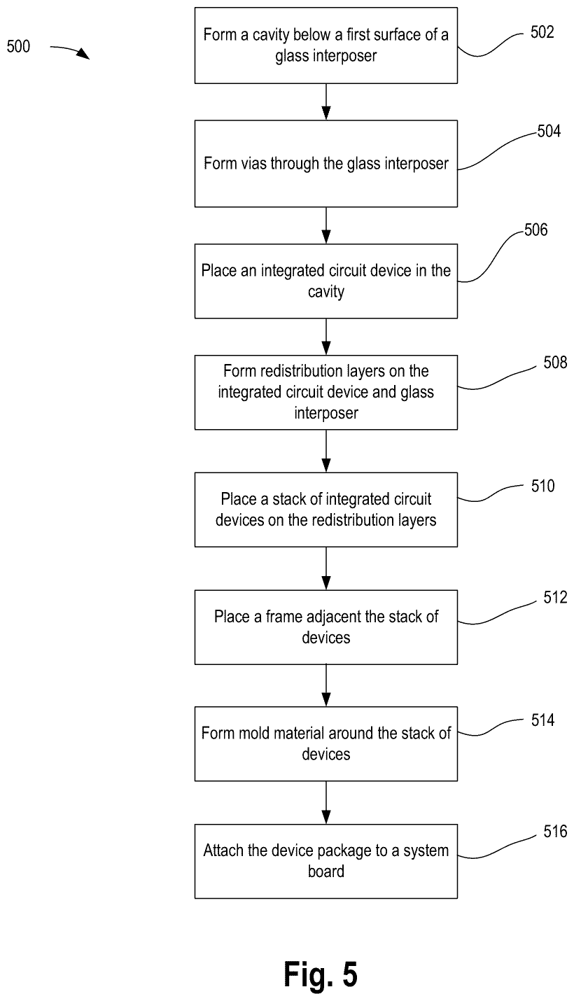

FIG. 5 illustrates a flowchart of a method of forming high performance glass architecture for stacked integrated circuit devices, in accordance with some embodiments. Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 500 begins with forming (502) a cavity below a first surface of a glass interposer. In some embodiments, such as assembly 200, interposer cavity 206 may be formed below upper interposer surface 204. Next, vias are formed (504) through the glass interposer. In some embodiments, such as assembly 210, vias 212 may be formed between upper interposer surface 204 and lower interposer surface 209. In some embodiments, vias 212 are also formed between cavity surface 208 and lower interposer surface 209.

Then, an integrated circuit device may be placed (506) in the cavity in the glass interposer. In some embodiments, such as assembly 220, device 222 may be placed inside interposer cavity 206 and attached to cavity surface 208. Next, redistribution layers are formed (508) on the integrated circuit device and glass interposer. In some embodiments, such as assembly 230, redistribution layers 232 embed device 222 within interposer cavity 206.

The method continues, in some embodiments, with placing (510) a stack of integrated circuit devices on the redistribution layers. In some embodiments, such as assembly 240, device stack 242 may include traditional solder bonding with redistribution layers 232 and direct chip to chip interconnect between integrated circuit devices. Next, a frame may be placed (512) adjacent the stack of integrated circuit devices. In some embodiments, such as assembly 250, frame 252 is placed on redistribution layers 232 surrounding device stack 242.

Next, mold material may be formed (514) around the stack of integrated circuit devices. In some embodiments, such as assembly 250, mold material 254 is deposited between device stack 242 and frame 252. Finally, the device package may be attached (516) to a system board. In some embodiments, solder bumps, such as solder bumps 324 may be formed on device package 302, allowing device package 302 to be soldered to system board 306.

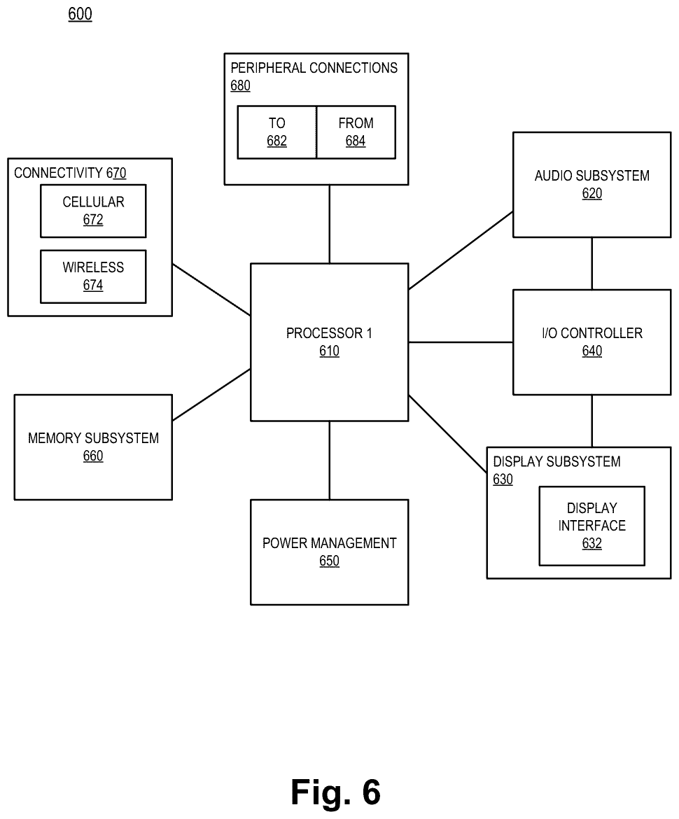

FIG. 6 illustrates a smart device or a computer system or a SoC (System-on-Chip) which includes high performance glass architecture for stacked integrated circuit devices, according to some embodiments. In some embodiments, computing device 600 represents a mobile computing device, such as a computing tablet, a mobile phone or smart-phone, a wireless-enabled e-reader, or other wireless mobile device. It will be understood that certain components are shown generally, and not all components of such a device are shown in computing device 600. In some embodiments, one or more components of computing device 600, for example processor 610 or I/O controller 640, include high performance glass architecture for stacked integrated circuit devices as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 600 includes a first processor 610. The various embodiments of the present disclosure may also comprise a network interface within 670 such as a wireless interface so that a system embodiment may be incorporated into a wireless device, for example, cell phone or personal digital assistant.

In one embodiment, processor 610 can include one or more physical devices, such as microprocessors, application processors, microcontrollers, programmable logic devices, or other processing means. The processing operations performed by processor 610 include the execution of an operating platform or operating system on which applications and/or device functions are executed. The processing operations include operations related to I/O (input/output) with a human user or with other devices, operations related to power management, and/or operations related to connecting the computing device 600 to another device. The processing operations may also include operations related to audio I/O and/or display I/O.

In one embodiment, computing device 600 includes audio subsystem 620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 600, or connected to the computing device 600. In one embodiment, a user interacts with the computing device 600 by providing audio commands that are received and processed by processor 610.

Display subsystem 630 represents hardware (e.g., display devices) and software (e.g., drivers) components that provide a visual and/or tactile display for a user to interact with the computing device 600. Display subsystem 630 includes display interface 632, which includes the particular screen or hardware device used to provide a display to a user. In one embodiment, display interface 632 includes logic separate from processor 610 to perform at least some processing related to the display. In one embodiment, display subsystem 630 includes a touch screen (or touch pad) device that provides both output and input to a user.

I/O controller 640 represents hardware devices and software components related to interaction with a user. I/O controller 640 is operable to manage hardware that is part of audio subsystem 620 and/or display subsystem 630. Additionally, I/O controller 640 illustrates a connection point for additional devices that connect to computing device 600 through which a user might interact with the system. For example, devices that can be attached to the computing device 600 might include microphone devices, speaker or stereo systems, video systems or other display devices, keyboard or keypad devices, or other I/O devices for use with specific applications such as card readers or other devices.

As mentioned above, I/O controller 640 can interact with audio subsystem 620 and/or display subsystem 630. For example, input through a microphone or other audio device can provide input or commands for one or more applications or functions of the computing device 600. Additionally, audio output can be provided instead of, or in addition to display output. In another example, if display subsystem 630 includes a touch screen, the display device also acts as an input device, which can be at least partially managed by I/O controller 640. There can also be additional buttons or switches on the computing device 600 to provide I/O functions managed by I/O controller 640.

In one embodiment, I/O controller 640 manages devices such as accelerometers, cameras, light sensors or other environmental sensors, or other hardware that can be included in the computing device 600. The input can be part of direct user interaction, as well as providing environmental input to the system to influence its operations (such as filtering for noise, adjusting displays for brightness detection, applying a flash for a camera, or other features).

In one embodiment, computing device 600 includes power management 650 that manages battery power usage, charging of the battery, and features related to power saving operation. Memory subsystem 660 includes memory devices for storing information in computing device 600. Memory can include nonvolatile (state does not change if power to the memory device is interrupted) and/or volatile (state is indeterminate if power to the memory device is interrupted) memory devices. Memory subsystem 660 can store application data, user data, music, photos, documents, or other data, as well as system data (whether long-term or temporary) related to the execution of the applications and functions of the computing device 600.

Elements of embodiments are also provided as a machine-readable medium (e.g., memory 660) for storing the computer-executable instructions. The machine-readable medium (e.g., memory 660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 670 includes hardware devices (e.g., wireless and/or wired connectors and communication hardware) and software components (e.g., drivers, protocol stacks) to enable the computing device 600 to communicate with external devices. The computing device 600 could be separate devices, such as other computing devices, wireless access points or base stations, as well as peripherals such as headsets, printers, or other devices.

Connectivity 670 can include multiple different types of connectivity. To generalize, the computing device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 680 include hardware interfaces and connectors, as well as software components (e.g., drivers, protocol stacks) to make peripheral connections. It will be understood that the computing device 600 could both be a peripheral device (“to” 682) to other computing devices, as well as have peripheral devices (“from” 684) connected to it. The computing device 600 commonly has a “docking” connector to connect to other computing devices for purposes such as managing (e.g., downloading and/or uploading, changing, synchronizing) content on computing device 600. Additionally, a docking connector can allow computing device 600 to connect to certain peripherals that allow the computing device 600 to control content output, for example, to audiovisual or other systems.

In addition to a proprietary docking connector or other proprietary connection hardware, the computing device 600 can make peripheral connections 680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
an interposer comprising glass;
one or more redistribution layers on a first interposer surface;
one or more conductive contacts on a second interposer surface opposite the first interposer surface;
one or more vias through the interposer coupling at least one of the conductive contacts on the second interposer surface with the redistribution layers on the first interposer surface;
an integrated circuit device embedded within a cavity in the interposer between the first and second interposer surfaces, the embedded integrated circuit device coupled with a first redistribution layers surface;
a stack of two or more integrated circuit devices coupled with a second redistribution layers surface opposite the first redistribution layers surface; and
mold material surrounding at least one side of the stack of two or more integrated circuit devices.

2. The apparatus of claim 1, wherein the stack of two or more integrated circuit devices comprises an integrated circuit device stacked on two or more integrated circuit devices having a same height.

3. The apparatus of claim 1, further comprising one or more vias through the interposer coupling at least one of the conductive contacts on the second interposer surface with the embedded integrated circuit device.

4. The apparatus of claim 1, wherein the embedded integrated circuit device comprises a device chosen from the group consisting of: high bandwidth memory (HBM), intelligent power device (IPD), photonic integrated circuit (PIC), and embedded passive components (EPC).

5. The apparatus of claim 1, wherein a midpoint of the stack of two or more integrated circuit devices is offset to a first side of a midpoint of the interposer, and wherein a midpoint of the embedded integrated circuit device is offset to a second side of the midpoint of the interposer opposite the first side of the midpoint of the interposer.

6. The apparatus of claim 1, further comprising a frame coupled with the mold material surrounding at least one side of the stack of two or more integrated circuit devices, the frame adjacent at least the one side of the stack of two or more integrated circuit devices.

7. The apparatus of claim 6, wherein the frame comprises glass, the glass comprising channels through which liquid may flow.

8. The apparatus of claim 6, wherein the frame comprises copper.

9. The apparatus of claim 6, wherein the frame comprises extensions of the interposer.

10. The apparatus of claim 6, wherein the frame is coupled with a bottom die of the stack of two or more integrated circuit devices.

11. A system comprising:
a host board;
an integrated circuit device package, the integrated circuit device package comprising:
an interposer comprising glass;
one or more redistribution layers on a first interposer surface;
one or more conductive contacts on a second interposer surface opposite the first interposer surface and coupled to the host board;
one or more vias through the interposer coupling at least one of the conductive contacts on the second interposer surface with the redistribution layers on the first interposer surface;
an integrated circuit device embedded within a cavity in the interposer between the first and second interposer surfaces, the embedded integrated circuit device coupled with a first redistribution layers surface;
a stack of two or more integrated circuit devices coupled with a second redistribution layers surface opposite the first redistribution layers surface; and
mold material surrounding at least one side of the stack of two or more integrated circuit devices; and
a power supply to provide power to the integrated circuit device package through the host board.

12. The system of claim 11, wherein the stack of two or more integrated circuit devices comprises an integrated circuit device stacked on two or more integrated circuit devices having a same height.

13. The system of claim 11, further comprising one or more vias through the interposer coupling at least one of the conductive contacts on the second interposer surface with the embedded integrated circuit device.

14. The system of claim 11, wherein the embedded integrated circuit device comprises a device chosen from the group consisting of: high bandwidth memory (HBM), intelligent power device (IPD), photonic integrated circuit (PIC), and embedded passive components (EPC).

15. The system of claim 11, wherein a midpoint of the stack of two or more integrated circuit devices is offset to a first side of a midpoint of the interposer, and wherein a midpoint of the embedded integrated circuit device is offset to a second side of the midpoint of the interposer opposite the first side of the midpoint of the interposer.

16. The system of claim 11, further comprising a frame coupled with the mold material surrounding at least one side of the stack of two or more integrated circuit devices, the frame adjacent at least the one side of the stack of two or more integrated circuit devices.

17. The system of claim 16, wherein the frame comprises glass, the glass comprising channels through which liquid may flow.

18. The system of claim 16, wherein the frame comprises copper.

19. A method comprising:
forming a cavity below a first surface of a glass interposer;
forming vias through the glass interposer from the first surface of the glass interposer to a second surface of the glass interposer;
placing an integrated circuit device in the cavity;
forming redistribution layers on the integrated circuit device and the first surface of the glass interposer; and
placing a stack of two or more integrated circuit devices on the redistribution layers.

20. The method of claim 19, further comprising forming mold material surrounding at least one side of the stack of two or more integrated circuit devices.

21. The method of claim 19, further comprising forming vias through the glass interposer from a surface of the cavity to the second surface of the glass interposer.

22. The method of claim 19, wherein placing a stack of two or more integrated circuit devices on the distribution layers comprises:
bonding two or more integrated circuit devices together with a die-to-die interface; and
bonding the stack of two or more integrated circuit devices on the distribution layers with a solder bond.

23. The method of claim 19, further comprising forming channels through which liquid may flow within the glass interposer.

24. The method of claim 19, further comprising placing a copper frame adjacent at least the one side of the stack of two or more integrated circuit devices.
